(19) United States
(12) Patent Application Publication
(10) Pub. No.: US 2007/0279260 A1
(43) Pub. Date: Dec. 6, 2007

(54) Apparatus and method for performing defect diagnosis of field device

(75) Inventors: Daisuke Harigane, Tokyo (JP); Seiichiro Takahashi, Tokyo (JP); Rie Kido, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: Yokogawa Electric Corporation, Musashino-shi (JP)

(21) Appl. No.: 11/802,332

(22) Filed: May 22, 2007

(30) Foreign Application Priority Data
May 30, 2006 (JP) 2006-149508

(51) Int. Cl. H03M 7/00

(52) U.S. Cl. 341/50

(57) ABSTRACT

A diagnosing apparatus includes, but is not limited to, a first functional unit and a second functional unit. The first functional unit may be configured to acquire at least one reference value for at least one diagnostic target, in accordance with at least one preset acquisition condition. The second functional unit may be configured to acquire at least one actually measured value for the at least one diagnostic target and compare the at least one actually measured value to the at least one reference value, in accordance with at least one preset application condition, thereby performing diagnosis of the at least one diagnostic target. The first and second functional units may be realized by, but are not limited to, any available control processing unit, processor, calculator or controller.

### BACKGROUND OF THE INVENTION

1. Field of the Invention

The present invention generally relates to a diagnosis apparatus and a diagnosis method. More specifically, the present invention relates to an apparatus and a method for performing defect diagnosis of field devices such as a differential pressure transmitter, a flowmeter and a valve positioner.

Priority is claimed on Japanese Patent Application No. 2006-149508, filed May 30, 2006, the content of which is incorporated herein by reference.

2. Description of the Related Art

All patents, patent applications, patent publications, scientific articles, and the like, which will hereinafter be cited or identified in the present application, will hereby be incorporated by reference in their entirety in order to describe more fully the state of the art to which the present invention pertains.

FIG. 5 is a schematic view illustrating the configuration of a conventional system for performing defect diagnosis of field devices. Field instruments F1, F2, - - - , Fn may be placed in a process apparatus in a plant. The field instruments F1, F2, - - - , Fn may be configured to measure various process values. Typical examples of the field instruments F1, F2, - - - , Fn may include, but are not limited to, a differential pressure transmitter, a flowmeter and a valve positioner.

A host device HT is configured to perform defect diagnosis of each of the field instruments F1, F2, - - - , Fn. The host device HT is connected to the field instruments F1, F2, - - - , Fn through bus lines. Each of the field instruments F1, F2, - - - , Fn transmits a process value through the bus line to the host device HT, so that the host device HT performs defect diagnosis of each of the field instruments F1, F2, - - - , Fn based on the process value. The host device HT includes a storage device that is configured to store a reference value for each of the field instruments F1, F2, - - - , Fn separately, wherein each reference value is previously given and each reference value is used to perform defect diagnosis of each of the field instruments F1, F2, - - - , Fn.

The reference value is a value of a predetermined parameter that is calculated based on a set of time series data. The time series data are of process values that are transmitted from the field instrument when the field instrument is placed in the normal state. A typical example of the parameter may include, but is not limited to, a statistical parameter such as an averaged value or a variance of time series data. The reference value can be needed in any case other than before the system is practiced.

FIG. 6 is a flow chart of defect diagnosis operations by the conventional host device HT. In Step S1, upon receipt of instructions to start diagnosis from an operator, the host device HT acquires, from the storage device, one or more reference values that correspond to target field instruments that are subject to diagnosis.

In Step S2, the host device HT determines whether a predetermined or preset diagnostic cycle of the target field instrument has come or not yet. If the diagnostic cycle has not yet come, then the host device HT remains in the stand-by state until the diagnostic cycle has come.

If the diagnostic cycle has come, then in Step S3, the host device HT determines whether or not the instructions to re-acquire the reference value are entered from an operator.

If the instructions to re-acquire the reference value are not entered, then in Step S4, the host device HT acquires the above-described parameter as an actually measured value. The parameter is calculated based on a set of time series data of process values that are transmitted from the target field instrument.

If the instructions to re-acquire the reference value are entered from an operator, then in Step S5, the host device HT re-acquires the reference value, and then in Step S4, the host device HT acquires the above-described parameter as an actually measured value. The re-acquisition of the reference value is that the host device HT calculates a new reference value based on a set of time series data of process values that are transmitted from a target field instrument, and then the host device HT overwrites the new reference value over the previously stored reference value.

In Step S6, the host device HT reads out the reference value of the target field instrument from the storage device. The host device HT compares the reference value to the above-described actually measured value, thereby performing the defect diagnosis of the target field instrument.

The host device HT performs the above-described set of processes in Steps S2 through S6 every diagnostic cycle. The reference value depends on the type of a target field instrument. The host device HT performs the above-described set of processes in Steps S2 through S6 every type of target field instruments.

As described above, if the instructions to re-acquire the reference value are entered from an operator, then the host device HT re-acquires the reference value. The reason for acquisition is that the reference value should be changed depending upon any environmental change, namely the state of operation of a plant depending upon the seasons or the load.

A conventional blockage diagnosis method has been known to diagnose blockage in impulse lines connected to the differential pressure transmitter. The determination of the impulse line blockage is performed based on a ratio of the reference value and the actually measured value. The reference value corresponds to the fluctuation variance of the differential pressure that is measured in the normal state. The actually measured value corresponds to the fluctuation variance of the differential pressure measured when the differential pressure transmitter with the impulse lines are diagnosed. The fluctuation variance of the differential pressure depends on not only blockage of the impulse lines but also the flow rate of a fluid in a pipe that is connected through the impulse lines to the differential pressure transmitter. In order to perform the accurate diagnosis, it is necessary to change the reference value in accordance with the variation in the flow rate of a fluid.

Typical examples of the cause for need to re-acquire the reference value may include, but are not limited to, the variation in the flow rate of a fluid, the change of the type of a target object, temperature variation, variation in noises around a target device or instrument, or the change in the state of operation of a plant. The state of operation of a plant may vary depending upon the seasons, the operating times, or the load.

An operator determines the need to re-acquire the reference value and enters the instructions to re-acquire the reference into the host device. Namely, the operator determines the need to re-acquire the reference value by taking into consideration the state of operation of a plant every diagnostic cycle, and operates the host device. The conventional apparatus gives an operator heavy load and inefficient operations.

The reference value is updated or overwritten every time a new reference value is re-acquired. This overwrite system renders it impermissible to re-apply the once-overwritten reference value. An operator does unwillingly and inefficiently re-acquire the reference value every time the state of operation of a plant is changed. For example, a statistical parameter such as an averaged value or a variance may be used as the reference value, wherein the statistical parameter is calculated based on a set of time series data of process values that have been obtained from a target device or instrument. In this case, if the host device acquires the process values within intervals between communications that are engaged with process control, for example, one time every ten seconds, then it takes about 33 minutes to acquire a set of 200 time series data. Namely, it takes about 33 minutes every time the reference value is re-acquired. The re-acquisition of the reference value is inefficient and time-consuming procedure.

An operator might mistakenly fail to enter the necessary instructions to re-acquire the reference value into the host device, thereby obtaining incorrect diagnosis result.

In view of the above, it will be apparent to those skilled in the art from this disclosure that there exists a need for an improved apparatus and/or method. This invention addresses this need in the art as well as other needs, which will become apparent to those skilled in the art from this disclosure.

### SUMMARY OF THE INVENTION

Accordingly, it is a primary object of the present invention to provide an apparatus for performing diagnosis of a target object.

It is another object of the present invention to provide an apparatus for performing defect diagnosis of a target instrument.

It is a further object of the present invention to provide an apparatus for performing defect diagnosis of a target instrument, which is free from the above disadvantages.

It is a still further object of the present invention to provide an apparatus for performing defect diagnosis of a target instrument, which reduces the burden of an operator.

It is yet a further object of the present invention to provide an apparatus for performing defect diagnosis of a target instrument efficiently and accurately.

It is an additional object of the present invention to provide a method of performing diagnosis of a target object.

It is another object of the present invention to provide a method of performing defect diagnosis of a target instrument.

It is still another object of the present invention to provide a method of performing defect diagnosis of a target instrument, which is free from the above disadvantages.

It is yet another object of the present invention to provide a method of performing defect diagnosis of a target instrument, which reduces the burden of an operator.

It is moreover object of the present invention to provide a method of performing defect diagnosis of a target instrument efficiently and accurately.

In accordance with a first aspect of the present invention, a diagnosing apparatus may include, but is not limited to, an acquisition condition storing unit, a reference value acquisition unit, a reference value storing unit, an application condition storing unit, and a diagnosing unit. The acquisition condition storing unit may be configured to store at least one acquisition condition for at least one diagnostic target. The at least one acquisition condition provides for at least one acquisition timing to acquire at least one reference value. The reference value acquisition unit may be configured to acquire the at least one reference value in accordance with the at least one acquisition condition and based on at least one first process value. The at least one first process value is supplied from the at least one diagnostic target when the at least one diagnostic target is placed in the normal state. The reference value storing unit may be configured to store the at least one reference value. The application condition storing unit may be configured to store at least one application condition for the at least one diagnostic target. The at least one application condition provides for at least one application timing to apply the at least one reference value that is stored in the reference value storing unit. The diagnosing unit may be configured to read the at least one reference value out of the reference value storing unit in accordance with the at least one application condition. The diagnosing unit may be configured to acquire at least one actually measured value in accordance with the at least one application condition and based on at least one second process value. The at least one second process value is supplied from the at least one diagnostic target. The diagnosing unit may also be configured to compare the at least one actually measured value to the at least one reference value and perform diagnosis of the at least one diagnostic target.

Each of the acquisition condition storing unit, the reference value storing unit, and the application condition storing unit may be realized by any available storing media or device. The reference value acquisition unit and the diagnosing unit may be realized by, but are not limited to, any available control processing unit, processor, calculator or controller.

The at least one acquisition condition may provide for acquiring the at least one reference value when a predetermined time period has lapsed.

The at least one acquisition condition may provide for acquiring the at least one reference value in accordance with a result of comparison between a threshold and at least one third process value. The at least one third process value may be supplied from at least one of the at least one diagnostic target and at least one non-target.

The at least one acquisition condition may provide for acquiring the at least one reference value in accordance with a result of comparison between a threshold and a parameter. The parameter may be calculated based on a set of time series data of process value that are supplied from at least one of the at least one diagnostic target and at least one non-target.

The at least one acquisition condition may provide for acquiring the at least one reference value when process value become stable, which are supplied from at least one of the at least one diagnostic target and at least one non-target.

The at least one acquisition condition may provide for acquiring the at least one reference value when process sequence is changed.

The at least one application condition may provide for reading the at least one reference value out of the reference value storing unit when a predetermined time period has lapsed.

The at least one application condition may provide for reading the at least one reference value out of the reference value storing unit in accordance with a result of comparison between a threshold and at least one third process value. The at least one third process value may be supplied from at least one of the at least one diagnostic target and at least one non-target.

The at least one application condition may provide for reading the at least one reference value out of the reference value storing unit in accordance with a result of comparison between a threshold and a parameter. The parameter may be calculated based on a set of time series data of process value that are supplied from at least one of the at least one diagnostic target and at least one non-target.

The diagnosing apparatus may further include, but is not limited to, an input unit that is configured to allow entries of the at least one acquisition condition and the at least one application condition. The acquisition condition storing unit may be configured to store the at least one acquisition condition that is entered through the input unit. The application condition storing unit may be configured to store the at least one application condition that is entered through the input unit.

In accordance with a second aspect of the present invention, a diagnosing method may include, but is not limited to, the following processes. At least one acquisition condition is stored for at least one diagnostic target separately. The at least one acquisition condition may provide for at least one acquisition timing to acquire at least one reference value. At least one application condition may be stored for the at least one diagnostic target separately. The at least one application condition may provide for at least one application timing to apply the at least one reference value. The at least one reference value may be acquired in accordance with the at least one acquisition condition and based on at least one first process value. The at least one first process value may be supplied from the at least one diagnostic target when the at least one diagnostic target is placed in the normal state. The at least one reference value may be stored for the at least one diagnostic target. The at least one reference value may be read in accordance with the at least one application condition. At least one actually measured value may be acquired in accordance with the at least one application condition and based on at least one second process value. The at least one second process value may be supplied from the at least one diagnostic target. The at least one actually measured value may be compared to the at least one reference value, thereby performing diagnosis of the at least one diagnostic target.

In accordance with a third aspect of the present invention, a diagnosing apparatus may include, but is not limited to, a first functional unit and a second functional unit. The first functional unit may be configured to acquire at least one reference value for at least one diagnostic target, in accordance with at least one preset acquisition condition. The second functional unit may be configured to acquire at least one actually measured value for the at least one diagnostic target and compare the at least one actually measured value to the at least one reference value, in accordance with at least one preset application condition, thereby performing diagnosis of the at least one diagnostic target. The first and second functional units may be realized by, but are not limited to, any available control processing unit, processor, calculator or controller.

The first functional unit may be configured to calculate the at least one reference value based on at least one first process value. The at least one first process value may be supplied from the at least one diagnostic target when the at least one diagnostic target is placed in the normal state. The second functional unit may be configured to calculate the at least one actually measured value based on at least one second process value. The at least one second process value may be supplied from the at least one diagnostic target when the at least one diagnostic target is subject to diagnosis.

The diagnosing apparatus may further include, but is not limited to, a first storing unit, a second storing unit, and a third storing unit. The first storing unit may be configured to store the at least one preset acquisition condition that is associated with the at least one diagnostic target. The second storing unit may be configured to store the at least one preset application condition that is associated with the at least one diagnostic target. The third storing unit may be configured to store the at least one reference value.

These and other objects, features, aspects, and advantages of the present invention will become apparent to those skilled in the art from the following detailed descriptions taken in conjunction with the accompanying drawings, illustrating the embodiments of the present invention.

### BRIEF DESCRIPTION OF THE DRAWINGS

Referring now to the attached drawings which form a part of this original disclosure:

FIG. 1 is a schematic view illustrating the configuration of a system for performing defect diagnosis of field instruments in accordance with a first embodiment of the present invention;

FIG. 2 is a flow chart illustrating operations of a host device shown in FIG. 1;

FIG. 3A is a view illustrating an example of a reference value acquisition condition that is stored in an acquisition condition database;

FIG. 3B is a view illustrating an example of a reference value application condition that is stored in an acquisition application database;

FIG. 4 is a view illustrating an example of reference values for each of field instruments, which are stored in a reference value database shown in FIG. 1;

FIG. 5 is a schematic view illustrating the configuration of a conventional system for performing defect diagnosis of field devices; and

FIG. 6 is a flow chart of defect diagnosis operations by a conventional host device.

### DETAILED DESCRIPTION OF THE INVENTION

Selected embodiments of the present invention will now be described with reference to the drawings. It will be apparent to those skilled in the art from this disclosure that the following descriptions of the embodiments of the present invention are provided for illustration only and not for the purpose of limiting the invention as defined by the appended claims and their equivalents.

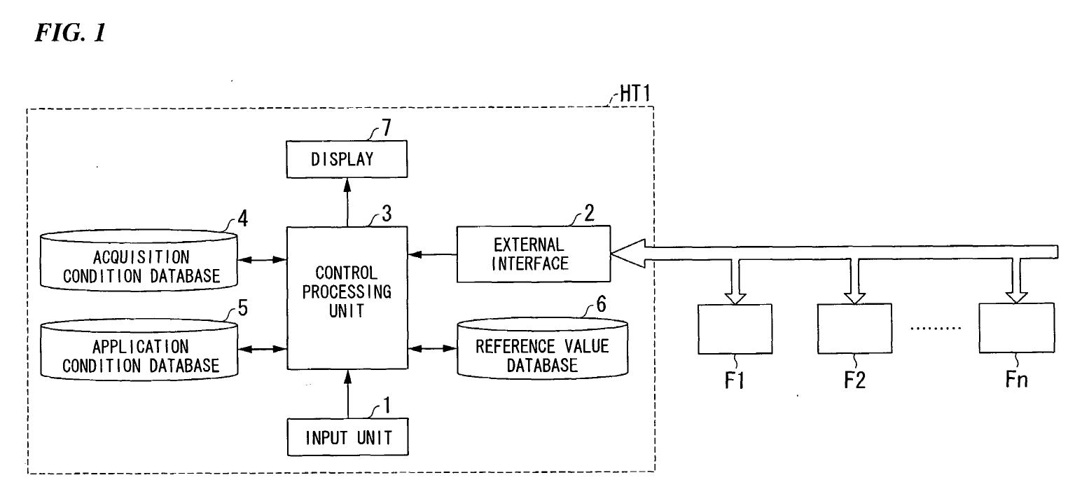

FIG. 1 is a schematic view illustrating the configuration of a system for performing defect diagnosis of field instruments in accordance with a first embodiment of the present invention. Field instruments F1, F2, - - - , Fn may be placed in a process apparatus in a plant. The field instruments F1, F2, - - - , Fn may be configured to measure various process values. Typical examples of the field instruments F1, F2, - - - , Fn may include, but are not limited to, a differential pressure transmitter, a flowmeter and a valve positioner.

A host device HT 1 is configured to perform defect diagnosis of each of the field instruments F1, F2, - - - , Fn. Namely, the host device HT1 may serve as an apparatus for performing defect diagnosis of each of the field instruments F1, F2, - - - , Fn. The host device HT is connected to the field instruments F1, F2, - - - , Fn through bus lines. The host device HT1 may be realized by, but not limited to, a personal computer.

The host device HT1 may include, but is not limited to, an input unit 1, an external interface 2, a control processing unit 3, an acquisition condition database 4, an application condition database 5, a reference value database 6, and a display 7.

The input unit 1 may be realized by, but is not limited to, a keyboard of the personal computer. The input unit 1 may be functionally coupled to the control processing unit 3. The input unit 1 may be configured to transmit an operation signal to the control processing unit 3. The operation signal indicates the input of operation by an operator.

The external interface 2 may be connected to the field instruments F1, F2, - - - , Fn through bus lines. Each of the filed instruments F1, F2, - - - , Fn measures a process value and transmits the measured process value through the bus line to the external interference 2. The external interface 2 may be configured to receive the measured process value from each of the field instruments F1, F2, - - - , Fn and transmit the process value to the control processing unit 3.

The control processing unit 3 may be functionally coupled to the input unit 1, the external interface 2, the acquisition condition database 4, the application condition database 5, the reference value database 6, and the display 7. The control processing unit 3 may be configured to receive the input operation signal from the input unit 1. The control processing unit 3 may be configured to receive the process values from the external interface 2. The control processing unit 3 may be configured to control overall operations of the host device HT1 based on the operation signal and the process values.

The host device HT1 may be configured to allow an operator to operate the input unit 1 so as to enter a reference value acquisition condition and a reference value application condition. The input unit 1 may be configured to transmit the reference value acquisition condition and the reference value application condition to the control processing unit 3. The control processing unit 3 may be configured to store the reference value acquisition condition in the acquisition condition database 4. The control processing unit 3 may be configured to store the reference value application condition in the application condition database 5.

The reference value acquisition condition may provide for the timing of acquiring the reference value. The acquisition of the reference value can be performed by calculating the reference value from a set of time series data of process values of a target field instrument F. The process values are supplied by the external interface 2. The reference value application condition may provide for the timing of applying the reference value that has been stored in the reference value database 6.

The reference value is the value of a predetermined parameter that is calculated based on a set of time series data of process values. The process values have been given by a target field instrument that has been placed in the normal state. Typically, the process value may be, but is not limited to, a statistical parameter such as an averaged value or a variance of time series data.

The control processing unit 3 may be configured to acquire a new reference value in accordance with the acquisition timing provided for by the reference value acquisition condition. Namely, in accordance with the acquisition timing, the control processing unit 3 acquires a set of time series data of process values of the target field instrument F from the external interface 2, so as to calculate the reference value based on the set of time series data. The control processing unit 3 may be configured to the reference value in the reference value database 6.

The control processing unit 3 may be configured to perform defect diagnosis in accordance with the application timing provided for by the reference value application condition. Namely, in accordance with the application timing, the control processing unit 3 reads the reference value out of the reference value database 6. The control processing unit 3 calculates an actually measured value as a statistical parameter from a set of time series data of current process values that are currently given by the target field instrument. The control processing unit 3 compares the currently measured value to the reference value and performs defect diagnosis of the target field instrument based on a result of the comparison.

Under the control by the control processing unit 3, the acquisition condition database 4 may be configured to store the reference value acquisition condition for every field instrument F that is subject to the diagnosis.

Under the control by the control processing unit 3, the application condition database 5 may be configured to store the reference value application condition for every field instrument F that is subject to the diagnosis.

Under the control by the control processing unit 3, the reference value database 6 may be configured to store the newly acquired reference value for every field instrument F that is subject to the diagnosis. The reference value database 6 may be configured to store a standard reference value for every field instrument F that is subject to the diagnosis. The standard reference value has been preset or predetermined.

The display unit 7 may be realized by, but is not limited to, a liquid crystal monitor. Under the control by the control processing unit 3, the display unit 7 may be configured to display a condition input screen that allows an operator to enter the reference value acquisition condition and the reference value application condition into the input unit 1. The display unit 7 may be configured to display a result of defect diagnosis of every target field instrument.

The following descriptions are directed to operations of the diagnosis system, particularly to operations of the host device HT1.

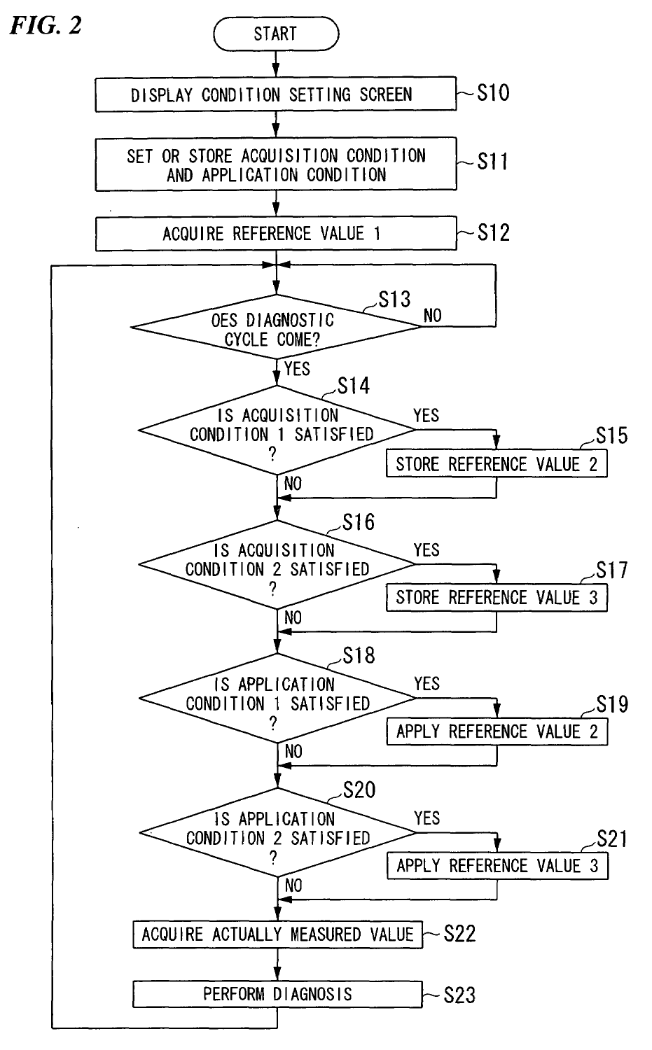

FIG. 2 is a flow chart illustrating operations of a host device HT1 shown in FIG. 1. In Step S10, the control processing unit 3 receives operator's instructions to start the diagnosis from the input unit 1. The control processing unit 3 renders the display unit 7 displaying the condition input screen.

In Step S11, the condition input screen of the display unit 7 permits the operator to enter the reference value acquisition condition and the reference value application condition into the input unit 1 for every target field instrument F. The input unit 1 transmits the reference value acquisition condition and the reference value application condition to the control processing unit 3. The control processing unit 3 stores the reference value acquisition condition in the acquisition condition database 4 for every target field instrument F. The control processing unit 3 also stores the reference value application condition in the application condition database 5 for every target field instrument F.

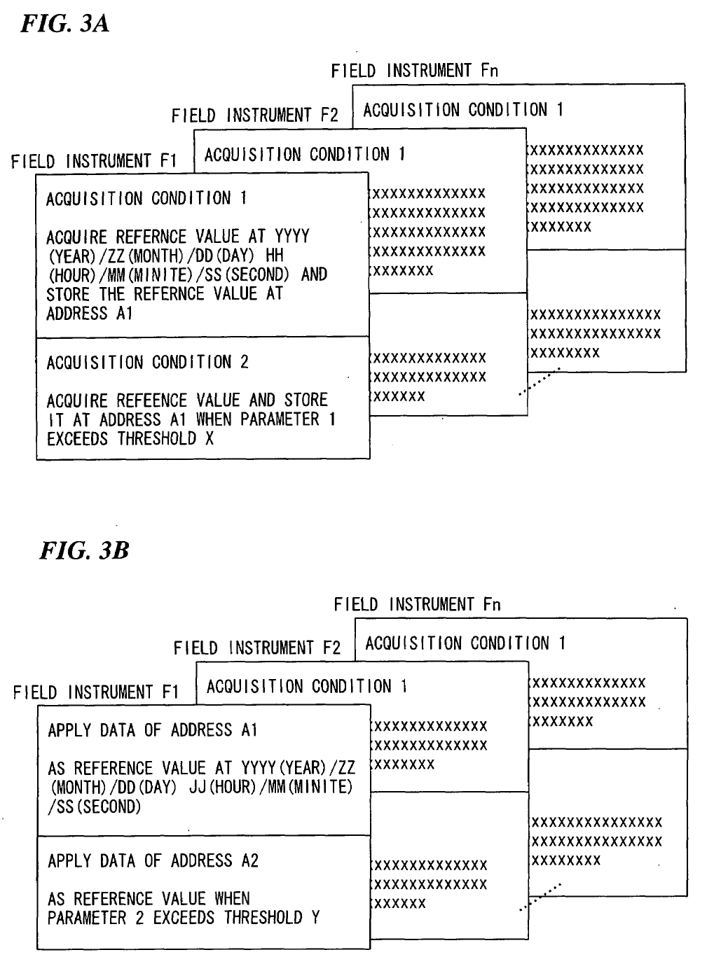

FIG. 3A is a view illustrating an example of the reference value acquisition condition that is stored in the acquisition condition database 4. In this example, the acquisition condition database 4 stores the reference value acquisition condition 1 for each of the first, second, - - - , n-th field instruments F1, F2, - - - , Fn independently. The first reference value acquisition condition 1 provides for the acquisition timing to re-acquire the reference value at a predetermined time “YYYY(year)/ZZ(month)/DD(day)HH(hour)/MM(minute)/SS(second)” and store the reference value at an address “A1”. The second reference value acquisition condition 2 provides for the acquisition timing to re-acquire the reference value when a parameter 1 exceeds a threshold X, and store the reference value at an address “A2”. The addresses “A1” and “A2” are addresses of the reference value database 6.

The first reference value acquisition condition 1 provides for the acquisition timing based on the predetermined time. The first reference value acquisition condition 1 may be used to automatically re-acquire the reference value at the predetermined time. The use of the first reference value acquisition condition 1 may be effective in case that the plant operating status varies depending on the seasons and the operating time.

The second reference value acquisition condition 2 provides for the acquisition timing based on a result of comparison between the parameter 1 and the threshold X. The second reference value acquisition condition 2 may be used to automatically re-acquire the reference value when a predetermined physical quantity such as the flow rate or the temperature of a measuring target exceeds the preset threshold X. Typical examples of the parameter 1 may include, but are not limited to, process values that are given by the other field instrument or instruments and a predetermined parameter that is calculated from a set of time series data of the process values.

The reference value acquisition condition should not be limited to the above-illustrated examples. In another case, the reference value acquisition condition can provide for the acquisition timing to re-acquire the reference value when the process values, which are given by the target or other field instruments, become stable. In still another case, the reference value acquisition condition can provide for the acquisition timing to re-acquire the reference value when the process sequence is changed. The change of process sequence may typically be the change in the order or sequence of processes. Detection of any process sequence change may be realized by, but not limited to, monitoring any change of predetermined process values or parameters. In yet another case, the reference value acquisition condition can provide for the acquisition timing to re-acquire the reference value when the type of a measuring target is changed or when noise around the target field instrument is changed.

One or more reference value acquisition conditions can be used to provide for the acquisition timing. In some cases, the reference value acquisition can be made when at least one of the plural reference value acquisition conditions is satisfied. In other cases, the reference value acquisition can be made when all of the plural reference value acquisition conditions are satisfied.

FIG. 3B is a view illustrating an example of the reference value application condition that is stored in the acquisition application database 5. In this example, the application condition database 5 stores the reference value application condition 1 for each of the first, second, - - - , n-th field instruments F1, F2, - - - , Fn independently. The first reference value acquisition condition 1 provides for the application timing to apply the reference value, which is stored at the address “A1”, at a predetermined time “YYYY(year)/ZZ(month)/ DD(day)JJ(hour)/MM(minute)/SS(second)”. The second reference value application condition 2 provides for the application timing to apply the reference value, which is stored at the address “A2”, when a parameter 2 exceeds a threshold Y, and store the reference value at an address “A2”. The addresses “A1” and “A2” are addresses of the reference value database 6.

The first reference value application condition 1 provides for the application timing based on the predetermined time. The first reference value application condition 1 may be used to automatically apply the reference value at the predetermined time. The use of the first reference value application condition 1 may be effective in case that the plant operating status varies depending on the seasons and the operating time.

The second reference value acquisition condition 2 provides for the application timing based on a result of comparison between the parameter 2 and the threshold Y The second reference value acquisition condition 2 may be used to automatically apply the reference value when a predetermined physical quantity such as the flow rate or the temperature of a measuring target exceeds the preset threshold Y The reference value that has been re-acquired based on the plant operating status can be used or re-used when a predetermined application condition is satisfied. Typical examples of the parameter 2 may include, but are not limited to, process values that are given by the other field instrument or instruments and a predetermined parameter that is calculated from a set of time series data of the process values.

The reference value application condition should not be limited to the above-illustrated examples. In another case, the reference value application condition can provide for the application timing to apply the reference value when the process values, which are given by the target or other field instruments, become stable. In still another case, the reference value application condition can provide for the application timing to apply the reference value when the process sequence is changed. In yet another case, the reference value application condition can provide for the application timing to apply the reference value when the type of a measuring target is changed or when noise around the target field instrument is changed.

One or more reference value application conditions can be used to provide for the application timing. In some cases, the reference value application can be made when at least one of the plural reference value application conditions is satisfied. In other cases, the reference value application can be made when all of the plural reference value application conditions are satisfied.

In Step S12, the control processing unit 3 acquires an initially set reference value 1 from the reference value database 6. The initially set reference value 1 has been initially set and stored in the reference value database 6. For simplification of the descriptions, it is hereby assumed that the field instrument F1 is subject to the diagnosis.

In Step S13, the control processing unit 3 determines whether a predetermined or preset diagnostic cycle of the target field instrument F1 has come or not yet. If in Step S13 the control processing unit 3 determines that the diagnostic cycle has not yet come, then the control processing unit 3 places the host device HT in the stand-by state until the diagnostic cycle has come.

If in Step S13 the control processing unit 3 determines that the diagnostic cycle has come, then in Step S14 the control processing unit 3 determines whether or not a reference value acquisition condition 1 of the field instrument F1 is satisfied, wherein the reference value acquisition condition 1 is stored in the acquisition condition database 4.

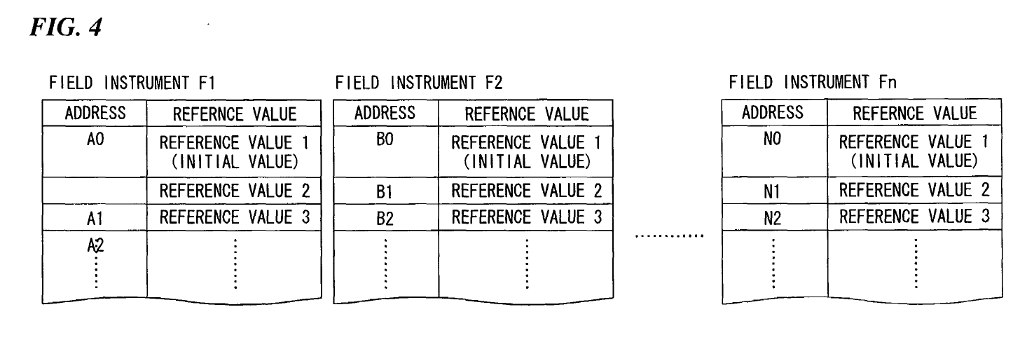

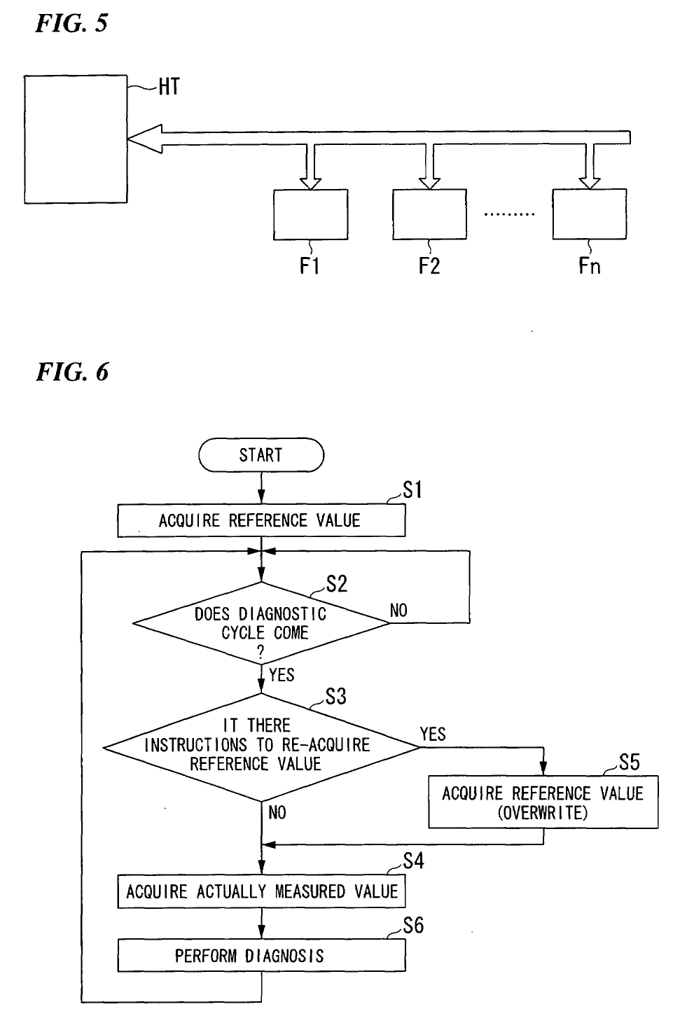

If in Step S14 the control processing unit 3 determines that the reference value acquisition condition 1 is satisfied, then in Step S15 the control processing unit 3 calculates a new reference value 2 from a set of time series data of the process values of the filed instrument F1. Further, the control processing unit 3 stores the new reference value 2 at the address “A1” in the reference value database 6. The process values are given by the field instrument F1 through the external interface 2. FIG. 4 is a view illustrating an example of reference values for each of field instruments F1, F2, - - - , Fn, which are stored in the reference value database 6 shown in FIG. 1.

After the control processing unit 3 has stored the new reference value 2, then in Step S16 the control processing unit 3 determines whether or not a reference value acquisition condition 2 of the field instrument F1 is satisfied, wherein the reference value acquisition condition 2 is stored in the acquisition condition database 4.

If the control processing unit 3 determines that the reference value acquisition condition 1 is not satisfied, then also the determination process in Step S16 is performed by the control processing unit 3.

If in Step S16 the control processing unit 3 determines that the reference value acquisition condition 2 is satisfied, then in Step S17 the control processing unit 3 calculates a new reference value 3 from a set of time series data of the process values of the filed instrument F2. Further, as shown in FIG. 4, the control processing unit 3 stores the new reference value 3 at the address “A2” in the reference value database 6. The process values are given by the field instrument F2 through the external interface 2.

After the control processing unit 3 has stored the new reference value 3, then in Step S18 the control processing unit 3 determines whether or not a reference value application condition 1 of the field instrument F1 is satisfied, wherein the reference value application condition 1 is stored in the application condition database 5.

If the control processing unit 3 determines that the reference value acquisition condition 2 is not satisfied, then also the determination process in Step S18 is performed by the control processing unit 3.

If in Step S18 the control processing unit 3 determines that the reference value application condition 1 is satisfied, then in Step S19 the control processing unit 3 acquires or applies the reference value 2 that is stored at the address “A1” in the reference value database 6.

If in Step S18 the control processing unit 3 determines that the reference value application condition 1 is not satisfied, then in Step S20 the control processing unit 3 determines whether or not a reference value application condition 2 of the field instrument F1 is satisfied, wherein the reference value application condition 2 is stored in the application condition database 5.

If in Step S20 the control processing unit 3 determines that the reference value application condition 2 is satisfied, then in Step S21 the control processing unit 3 acquires or applies the reference value 3 that is stored at the address “A2” in the reference value database 6.

After in Step S21 the control processing unit 3 acquires or applies the reference value 3, then in Step S22 the control processing unit 3 calculates an actually measured value from a set of time series data of process values which are given by the field instrument F1. The process values are supplied through the external interface 2.

If in Step S20 the control processing unit 3 determines that the reference value application condition 2 is not satisfied, then in Step S22 the control processing unit 3 calculates the actually measured value in the manner as described above.

After in Step S22 the control processing unit 3 acquires the actually measured value, then in Step S23 the control processing unit 3 compares the actually measured value to the reference value 2 or 3 and performs defect diagnosis of the field instrument F1. The actually measured value was acquired in Step S22. The reference value 2 was acquired in Step S19. The reference value 3 was acquired in Step S21. The control processing unit 3 renders the display unit 7 displaying the result of diagnosis of the target field instrument F1.

The control processing unit 3 performs the above-described processes in Steps S13 to S23 every diagnostic cycle.

It will be understood that the above-descriptions for the processes are applicable to the case in which field instrument or instruments other than the field instrument F1 are subject to the diagnosis.

If plural field instruments are subject to the diagnosis, then the control processing unit 3 performs the above-described processes in Steps S12 to S23 for every target field instrument.

As described above, the control processing unit 3 confirms the reference value acquisition condition and re-acquires the reference value every diagnostic cycle. Notwithstanding, it may be possible as a modification that the control processing unit 3 confirms the reference value acquisition condition and re-acquires the reference value in time periods other than the diagnostic cycles or any routine other than the diagnostic cycles.

As described above, the control processing unit 3 may be configured to automatically acquire a reference value in accordance with a preset reference value acquisition condition, wherein the reference value depends on the plant operating status. This configuration can reduce the burden of an operator so that an operator needs to initially set both the reference value acquisition condition and the reference value application condition. This configuration can realize highly efficient defect diagnosis.

In the prior art, an operator needs to determine the reference value re-acquisition timing every time. This means that an operator may mistakenly fail to determine the necessary re-acquisition timing.

The control processing unit 3 may be configured to automatically re-acquire the reference value every time the preset reference value acquisition condition is satisfied. This configuration for the reference value automatic re-acquisition can prevent an operator from mistaking in re-acquiring the reference value and thus does ensure the accuracy or correctness of the defect diagnosis.

The reference value database 6 may be configured to store not only the currently acquired reference value but also one or more past-acquired reference values so as to allow the control processing unit 3 to apply the past-acquired reference value again if necessary. This configuration of the reference value database 6 may improve the efficiency of defect diagnosis.

The above-described configuration of the defect diagnosis system may be modified as follows. It is assumed that the host device HT1 is functionally coupled to a thermometer, a flowmeter and a differential pressure transmitter, wherein the flowmeter and the differential pressure transmitter are subject to the diagnosis. A reference value acquisition condition is preset for the flowmeter and the differential pressure transmitter. A reference value application condition is also preset for the flowmeter and the differential pressure transmitter. The reference value acquisition condition is preset so as to provide for the acquisition timing to acquire the reference value and store it at the address “A1” when the temperature that is measured by the thermometer exceeds a threshold X. The reference value application condition is preset so as to provide for the application timing to apply the reference value at the address “A1” when the temperature that is measured by the thermometer exceeds a different threshold X′.

It is assumed that under the above-described conditions, the host device HT1 performs the defect diagnosis of each of the flowmeter and the differential pressure transmitter. In this case, the host device HT1 may be configured to acquire individual reference values for the flowmeter and the differential pressure transmitter, based on single condition that is determined with reference to information being supplied by the non-target field instrument, namely the thermometer. Namely, the host device HT1 may be configured to automatically schedule for acquiring individual reference values for plural target objects.

The term “configured” is used to describe a component, section or part of a device includes hardware and/or software that is constructed and/or programmed to carry out the desired function.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A diagnosing apparatus comprising:
an acquisition condition storing unit configured to store at least one acquisition condition for at least one diagnostic target, the at least one acquisition condition providing for at least one acquisition timing to acquire at least one reference value;
a reference value acquisition unit configured to acquire the at least one reference value in accordance with the at least one acquisition condition and based on at least one first process value, the at least one first process value being supplied from the at least one diagnostic target when the at least one diagnostic target is placed in the normal state;
a reference value storing unit configured to store the at least one reference value;
an application condition storing unit configured to store at least one application condition for the at least one diagnostic target, the at least one application condition providing for at least one application timing to apply the at least one reference value that is stored in the reference value storing unit; and
a diagnosing unit configured to read the at least one reference value out of the reference value storing unit in accordance with the at least one application condition, the diagnosing unit being configured to acquire at least one actually measured value in accordance with the at least one application condition and based on at least one second process value, the at least one second process value being supplied from the at least one diagnostic target, the diagnosing unit being configured to compare the at least one actually measured value to the at least one reference value and perform diagnosis of the at least one diagnostic target.

2. The diagnosing apparatus according to claim 1, wherein the at least one acquisition condition provides for acquiring the at least one reference value when a predetermined time period has lapsed.

3. The diagnosing apparatus according to claim 1, wherein the at least one acquisition condition provides for acquiring the at least one reference value in accordance with a result of comparison between a threshold and at least one third process value, the at least one third process value is supplied from at least one of the at least one diagnostic target and at least one non-target.

4. The diagnosing apparatus according to claim 1, wherein the at least one acquisition condition provides for acquiring the at least one reference value in accordance with a result of comparison between a threshold and a parameter, the parameter being calculated based on a set of time series data of process value that are supplied from at least one of the at least one diagnostic target and at least one non-target.

5. The diagnosing apparatus according to claim 1, wherein the at least one acquisition condition provides for acquiring the at least one reference value when process value become stable, which are supplied from at least one of the at least one diagnostic target and at least one non-target.

6. The diagnosing apparatus according to claim 1, wherein the at least one acquisition condition provides for acquiring the at least one reference value when process sequence is changed.

7. The diagnosing apparatus according to claim 1, wherein the at least one application condition provides for reading the at least one reference value out of the reference value storing unit when a predetermined time period has lapsed.

8. The diagnosing apparatus according to claim 1, wherein the at least one application condition provides for reading the at least one reference value out of the reference value storing unit in accordance with a result of comparison between a threshold and at least one third process value, the at least one third process value is supplied from at least one of the at least one diagnostic target and at least one non-target.

9. The diagnosing apparatus according to claim 1, wherein the at least one application condition provides for reading the at least one reference value out of the reference value storing unit in accordance with a result of comparison between a threshold and a parameter, the parameter being calculated based on a set of time series data of process value that are supplied from at least one of the at least one diagnostic target and at least one non-target.

10. The diagnosing apparatus according to claim 1, further comprising:
an input unit configured to allow entries of the at least one acquisition condition and the at least one application condition, and
wherein the acquisition condition storing unit is configured to store the at least one acquisition condition that is entered through the input unit, and
the application condition storing unit is configured to store the at least one application condition that is entered through the input unit.

11. A diagnosing method comprising:
storing at least one acquisition condition for at least one diagnostic target separately, the at least one acquisition condition providing for at least one acquisition timing to acquire at least one reference value;
storing at least one application condition for the at least one diagnostic target separately, the at least one application condition providing for at least one application timing to apply the at least one reference value; and
acquiring the at least one reference value in accordance with the at least one acquisition condition and based on at least one first process value, the at least one first process value being supplied from the at least one diagnostic target when the at least one diagnostic target is placed in the normal state;
storing the at least one reference value for the at least one diagnostic target;
reading the at least one reference value in accordance with the at least one application condition;
acquiring at least one actually measured value in accordance with the at least one application condition and based on at least one second process value, the at least one second process value being supplied from the at least one diagnostic target; and
comparing the at least one actually measured value to the at least one reference value to perform diagnosis of the at least one diagnostic target.

12. A diagnosing apparatus comprising:
a first functional unit configured to acquire at least one reference value for at least one diagnostic target, in accordance with at least one preset acquisition condition; and
a second functional unit configured to acquire at least one actually measured value for the at least one diagnostic target and compare the at least one actually measured value to the at least one reference value, in accordance with at least one preset application condition, thereby performing diagnosis of the at least one diagnostic target.

13. The diagnosing apparatus according to claim 12, wherein the first functional unit is configured to calculate the at least one reference value based on at least one first process value, the at least one first process value being supplied from the at least one diagnostic target when the at least one diagnostic target is placed in the normal state, and
the second functional unit is configured to calculate the at least one actually measured value based on at least one second process value, the at least one second process value being supplied from the at least one diagnostic target when the at least one diagnostic target is subject to diagnosis.

14. The diagnosing apparatus according to claim 12, further comprising:
a first storing unit configured to store the at least one preset acquisition condition that is associated with the at least one diagnostic target;
a second storing unit configured to store the at least one preset application condition that is associated with the at least one diagnostic target; and
a third storing unit configured to store the at least one reference value.
